(19) United States
(12) Patent Application Publication
(10) Pub. No.: US 2012/0255605 A1
(43) Pub. Date: Oct. 11, 2012

(54) METHOD OF MANUFACTURING SOLAR CELL ELECTRODE

(75) Inventor: NORIHIKO TAKEDA, KANAGAWA (JP)

(73) Assignee: E. I. DU PONT DE NEMOURS AND COMPANY, Wilmington, DE (US)

(21) Appl. No.: 13/440,132

(22) Filed: Apr. 5, 2012

Related U.S. Application Data
(60) Provisional application No. 61/472,381, filed on Apr. 6, 2011.

(51) Int. Cl. H01L 31/0224; H01L 21/288

(52) U.S. Cl. 136/256; 438/660; 257/E21.174

(57) ABSTRACT

The invention relates to a method of manufacturing a p-type electrode comprising the steps of: preparing an N-type base semiconductor substrate comprising an n-base layer, a p-type emitter on the n-base layer, a first passivation layer on the p-type emitter, and a second passivation layer on the n-base layer; applying a conductive paste onto the first passivation layer, wherein the conductive paste comprises (i) 100 parts by weight of a conductive powder comprising a metal selected from the group consisting of silver, nickel, copper and a mixture thereof, (ii) 0.3 to 8 parts by weight of aluminum powder with particle diameter of 3 to 11 μm, (iii) 3 to 22 parts by weight of a glass frit, and (iv) an organic medium; and firing the conductive paste.

### CROSS-REFERENCE TO RELATED APPLICATION

This application claims the benefit of U.S. Provisional Application No. 61/472,381, filed Apr. 6, 2011.

### FIELD OF THE INVENTION

This invention relates to an N-type base solar cell, more specifically a method of manufacturing a p-type electrode thereof.

### BACKGROUND OF THE INVENTION

Solar cell electrodes are required to have low electrical resistance to improve conversion efficiency (Eff) of solar cells. Especially in the case of N-type base solar cells, a solar cell electrode sometimes has insufficient electrical contacts to a semiconductor, resulting in lower conversion efficiencies.

US20100059106 discloses that a conductive paste to form a p-type electrode of an N-type base solar cell contains a conductive powder such as Ag, added particles such as Mo, Tc, Ru, Rh, Pd, W, Re, Os, Ir or Pt, a glass frit and a resin binder.

### BRIEF SUMMARY OF THE INVENTION

An objective of the present invention is to provide a method of manufacturing a p-type electrode which has lower contact resistance to a p-type emitter.

In an aspect of this present invention relates to a method of manufacturing a p-type electrode comprising the steps of: preparing an N-type base semiconductor substrate comprising an n-base layer, a p-type emitter on the n-base layer, a first passivation layer on the p-type emitter, and a second passivation layer on the n-base layer; applying a conductive paste onto the first passivation layer, wherein the conductive paste comprises (i) 100 parts by weight of a conductive powder comprising a metal selected from the group consisting of silver, nickel, copper and a mixture thereof, (ii) 0.3 to 8 parts by weight of aluminum powder with particle diameter of 3 to 11 μm, (iii) 3 to 22 parts by weight of a glass frit, and (iv) an organic medium; and firing the conductive paste.

Another aspect of this present invention relates to an N-type base solar cell comprising the p-type electrode formed by the method above.

The p-type electrode can have low contact resistance with a p-type emitter of a semiconductor substrate.

### BRIEF DESCRIPTION OF THE DRAWINGS

FIG. 1A to 1F are drawings for explaining a production process for manufacturing a p-type electrode of an N-type base solar cell.

FIG. 2 is a graph illustrating an effect of the aluminum powder content on Eff of a solar cell.

FIG. 3 is a graph illustrating an effect of the aluminum particle diameter on Eff of a solar cell.

FIG. 4 is a graph illustrating an effect of the firing temperature on Eff of a solar cell.

### DETAILED DESCRIPTION OF THE INVENTION

The present invention relates to a method of manufacturing a p-type electrode. The p-type electrode is an electrode formed on the surface of a passivation layer on a p-type emitter of an N-type base semiconductor substrate. The N-type base semiconductor substrate here comprises a p-type emitter, an n-base layer and passivation layers. The p-type emitter is formed at one side of the N-type base semiconductor substrate. The passivation layers are formed on the p-type emitter and the n-base layer respectively.

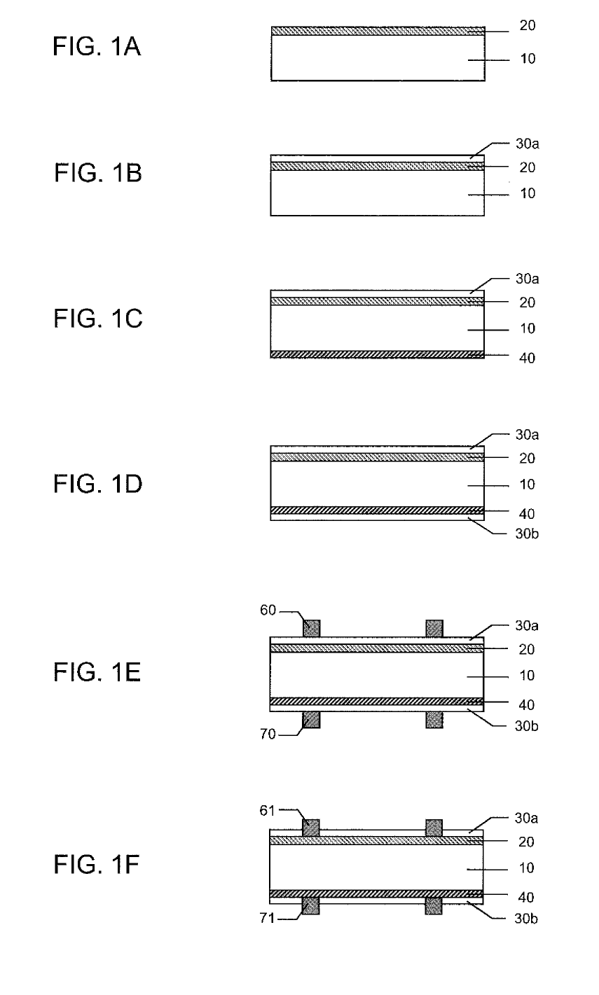

In an embodiment, the N-type base semiconductor substrate comprises a first passivation layer 30a, a p-type emitter 20, n-base layer 10, optionally n⁺-layer 40, and a second passivation layer 30b formed in this order as illustrated in FIG. 1D.

In an embodiment, the N-type base solar cell comprises a p-type electrode 61, a first passivation layer 30a, a p-type emitter 20, n-base layer 10, optionally n⁺-layer 40, a second passivation layer 30b, and an n-type electrode 71 formed in this order as illustrated in FIG. 1F, where the p-type electrode 61 passes through the first passivation layer 30a to have an electric contact with the p-type emitter 20 and the n-type electrode 71 passes through the second passivation layer 30b to have an electric contact with the n-base layer 10 or n⁺-layer 40.

The p-type emitter 20 can be defined as a semiconductor layer containing an impurity called acceptor dopant where the acceptor dopant introduces deficiency of valence electrons in the semiconductor element. In the p-type emitter, the acceptor dopant takes in free electrons from semiconductor element and consequently positively charged holes are generated in the valence band.

The n-base layer can be defined as a semiconductor layer containing an impurity called donor dopant where the donor dopant introduces extra valence electrons in the semiconductor element. In the n-base layer, free electrons are generated from the donor dopant in the conduction band.

By adding an impurity to an intrinsic semiconductor as above, electrical conductivity can be varied not only by the number of impurity atoms but also, by the type of impurity atom and the changes can be a thousand fold and a million fold.

Embodiments of the present invention are explained below with reference to the drawings in FIG. 1. The embodiments given below are examples for better understandings, and appropriate design changes are possible for those skilled in the art.

An embodiment of the invention is a method of manufacturing a p-type electrode.

FIG. 1A shows a cross-sectional view of an N-type base semiconductor substrate comprising an n-base layer 10 and a p-type emitter 20. The n-base layer 10 can be formed by being doped with a donor impurity such as phosphorus. The p-type emitter 20 can be formed, for example, by thermal diffusion of an acceptor dopant into an N-type base semiconductor substrate. In the case of silicon semiconductor, the acceptor dopant can be a boron compound such as boron tribromide (BBr₃). The thickness of the p-type emitter can be, for example, 0.1 to 10% of the N-type base semiconductor substrate thickness.

As shown in FIG. 1B, a first passivation layer 30a can be formed on the p-type emitter 20. The first passivation layer 30a can be 10 to 2000 Å thick. Silicon nitride (SiNₓ), silicon carbide (SiCₓ), Titanium oxide (TiO₂), Aluminum oxide (Al₂O₃), Silicon oxide (SiOₓ), Indium Tin Oxide (ITO), or a mixture thereof can be used as a material of the passivation layer 30. The first passivation layer 30a can be formed by, for example, plasma enhanced chemical vapor deposition (PECVD) of these materials.

In an embodiment, as shown in FIG. 1C, an n⁺-layer 40 can be formed at the other side of the p-type emitter 20, although it is not essential. The n⁺-layer 40 contains the donor impurity with higher concentration than that in the n-base layer 10. For example, the n⁺-layer 40 can be formed by thermal diffusion of phosphorus in the case of silicon semiconductor. By forming the n⁺-layer 40, the recombination of electrons and holes at the border of the n-base layer 10 and the n⁺-layer 40 can be reduced. When the n⁺-layer 40 is formed, the N-type base semiconductor substrate comprises the n⁺-layer between the n-base layer 10 and a passivation layer 30 which is formed in the next step.

As shown in FIG. 1D, a second passivation layer 30b is formed on the n⁺-layer 40. The N-type base semiconductor substrate comprising the n-base layer 10, the p-type emitter 20, the first passivation layer 30a and the second passivation layer 30b can be obtained here. The material and forming method of the second passivation layer 30b can be the same as the other one described above. However, the second passivation layer 30b on the n⁺-layer 40 can be different from the first passivation layer 30a in terms of its forming material or its forming method.

When the passivation layer(s) 30a and/or 30b is illuminated by sunlight in the operation of a solar cell, the passivation layer(s) 30a and/or 30b reduces the carrier recombination and reduces optical reflection losses so that it is also called an anti-reflection coating (“ARC”). In an embodiment, both sides of the n-base layer 10 and the p-type emitter 20 can be light receiving sides in the operation.

As shown in FIG. 1E, a conductive paste 60 for forming a p-type electrode is applied onto the first passivation layer 30a on the p-type emitter 20. The conductive paste 60 for forming the p-type electrode is described more in detail below. The conductive paste 70 for forming an n-type electrode is also applied onto the second passivation layers 30b on the n⁺-layer 40. When applying the conductive pastes, screen printing can be used.

In an embodiment, the conductive paste 70 on the second passivation layer 30b can be different in composition from the conductive paste 60 on the first passivation layer 30a. The composition of the conductive paste 70 can be adjusted depending on, for example, material or thickness of the second passivation layer 30b.

In another embodiment, the conductive paste 60 applied on the p-type emitter 20 and the conductive paste 70 applied on the n⁺-layer 40 can be same in composition. When both of the conductive pastes 60 and 70 are same, the manufacturing process can be simpler to result in reducing the production cost.

The conductive pastes 60 and 70 at the both side can be dried for 10 seconds to 10 minutes at 150° C.

Firing of the conductive pastes is then carried out. As shown FIG. 1F, the conductive pastes 60 and 70 fire through the passivation layers 30a and 30b during the firing so that a p-type electrode 61 and an n-type electrode 71 can have good electrical connections with the p-type emitter 20 and the n⁺-layer 40 respectively. When the connections between these electrodes and semiconductor are improved, the electrical properties of a solar cell will also be improved.

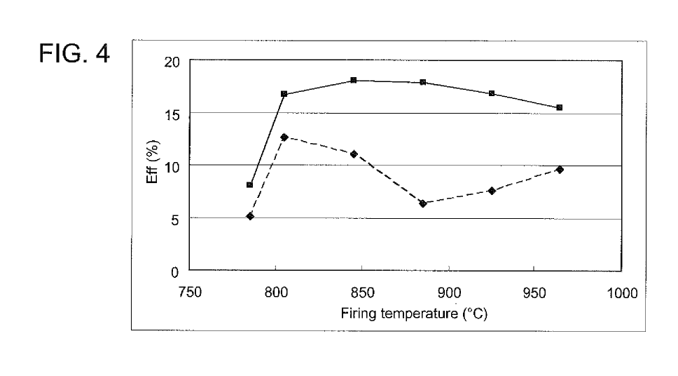

An infrared furnace can be used for the firing process. Firing conditions can be controlled in consideration of firing temperature and firing time. When the temperature is high, the time would be short. In view of productivity, high temperature and short firing time can be preferred. The firing peak temperature can be 800° C. to 1000° C. in an embodiment. The p-type electrode can stably obtain high Eff as shown in FIG. 4. The firing time from an entrance to an exit of a furnace can be from 30 seconds to 5 minutes, in another embodiment 40 seconds to 3 minutes.

In another embodiment, firing profile can be 10 to 60 seconds at over 400° C. and 2 to 10 seconds at over 600° C. The firing temperature is measured at the upper surface of the semiconductor substrate. With the firing temperature and time inside the range, less damage can occur to the semiconductor substrate during firing.

When actually operated, the solar cell can be installed with the n-base layer located at the backside which is the opposite side of the light receiving side of a solar cell. The solar cell can be also installed with the p-type emitter located at the backside which is the opposite side of the light receiving side of a solar cell.

Next, a conductive paste that is used in the method of manufacturing described above is explained in detail below. The conductive paste to form a p-type electrode comprises at least a conductive powder, aluminum powder, a glass frit and an organic medium.

### Conducting Powder

A conductive powder is a metal powder to transport electrical current in an electrode. The conductive powder comprises a metal selected from the group consisting of silver (Ag), copper (Cu), nickel (Ni) and a mixture thereof.

In an embodiment, the conductive powder can comprise a metal powder selected from the group consisting of Ag powder, Cu powder, Ni powder, alloy powder containing Ag, Cu or Ni and a mixture thereof. The conductive powder can be a mixture of these metal powders. Using such conductive powder with relatively high electrical conductivity, resistive power loss of a solar cell can be minimized. In an embodiment, a conductive powder can be Ag powder. Ag powder can be difficult to oxidize during firing in air to keep conductivity high.

In an embodiment, a conductive powder can be 80 to 98.5 weight percent (wt %), in another embodiment 83 to 95 wt %, in another embodiment 85 to 93 wt %, based on the total weight of the conductive powder, aluminum powder and glass frit. A conductive powder with such amount in the conductive paste can retain sufficient conductivity for solar cell applications.

In an embodiment, the conductive powder can be flaky or spherical in its shape.

There are no special restrictions on the particle diameter of the conductive powder from a viewpoint of technological effectiveness when used as typical electrically conducting paste. However, since the particle diameter affects the sintering characteristics of conductive powder, for example, large silver particles are sintered more slowly than silver particles of small particle diameter. For this reason, in an embodiment, the particle diameter can be 0.1 to 10 μm, in another embodiment, 1 to 7 μm, in another embodiment, 1.5 to 4 μm. In another embodiment, the conductive powder can be a mixture of two or more of conductive powders with different particle diameters.

The particle diameter (D50) is obtained by measuring the distribution of the particle diameters by using a laser diffraction scattering method and can be defined as D50. Microtrac model X-100 is an example of the commercially-available devices.

In an embodiment, the conductive powder can be of ordinary high purity of 99% or higher. However, depending on the electrical requirements of the electrode pattern, less pure silver can also be used.

### Aluminum Powder

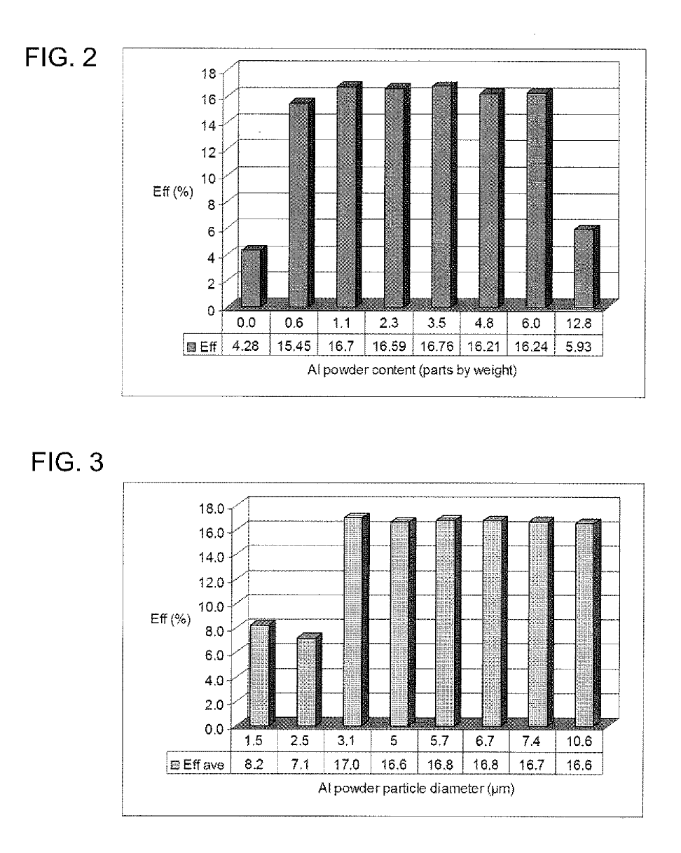

Aluminum (Al) powder is a metal powder containing at least Al. The purity of the Al powder can be 99% or higher. The Al powder in a conductive paste is 0.3 to 8 parts by weight based on 100 parts by weight of the conductive powder. By adding the Al powder to the conductive paste, electrical properties of a solar cell can be improved as shown in FIG. 2. In another embodiment, the Al powder can be not more than 6.5 parts by weight in another embodiment, not more than 4 parts by weight in another embodiment, 2.2 parts by weight in another embodiment, based on based on 100 parts by weight of the conductive powder. In an embodiment, Al powder can be not less than 0.7 parts by weight, in another embodiment, not more than 1.0 part by weight, based on based on 100 parts by weight of the conductive powder.

Particle diameter (D50) of the Al powder is 3 to 11 μm. With such particle diameter of Al powder, electrical properties of a solar cell can be improved as shown in FIG. 3. Accordingly, in an embodiment, the particle diameter (D50) of the Al powder can be not smaller than 3.1 μm, in another embodiment, not smaller than 3.3 μm. The upper limit of the particle diameter is not specifically restricted as long as it is 11 μm or smaller. However, in another embodiment it can be 8 μm or smaller, in another embodiment 6 μm, in another embodiment, not larger than 4 μm. The aluminum powder with such particle diameter can be dispersed well in the organic medium and appropriate to be applied on a substrate by screen printing. To measure the particle diameter (D50) of the Al powder, the same method as used for the conductive powder can be applied.

In an embodiment, the Al powder can be flaky, nodular, or spherical in its shape. The nodular powder is irregular particles with knotted, rounded shapes. In another embodiment, Al powder can be spherical.

### Glass Frit

Glass frits used in the conductive pastes described herein etch through the passivation layer during the consequent firing process and facilitate binding of the electrode to the semiconductor substrate and may also promote sintering of the conductive powder.

The glass frit is 3 to 22 parts by weight. By adding glass frit with such amount, Eff of a solar cell can become relatively high as shown in Table 2 in Example below. The glass frit can be 4 to 20 parts by weight in another embodiment, 5 to 15 parts by weight in another embodiment, 6 to 10 parts by weight in another embodiment, based on 100 parts by weight of the conductive powder. By adding glass frit with such amount, the p-type electrode can sufficiently adhere to a substrate.

The glass frit composition is not limited to specific compositions. A lead-free glass and a lead containing glass can be used, for example.

The glass frit composition is described herein as including percentages of certain components. Specifically, the percentages are the amount of the components used in the starting material that was subsequently processed to form a glass frit. In other words, the glass frit contains certain components, and the percentages of those components are expressed as a percentage of the corresponding oxide form. As recognized by one of skill in the art in glass chemistry, a certain portion of volatile species may be released during the process of making the glass.

In an embodiment, the glass frit comprises a lead containing glass frit containing one or more of oxides selected from a group consisting of lead oxide (PbO), silicon oxide (SiO₂), boron oxide (B₂O₃) and aluminum oxide (Al₂O₃).

In an embodiment, lead oxide (PbO) can be 40 to 80 mol %, in another embodiment 42 to 73 mol %, in another embodiment 45 to 68 mol % based on the total molar fraction of each component in the glass frit.

In an embodiment, silicon oxide (SiO₂) can be 0.5 to 40 mol %, in another embodiment 1 to 33 mol %, in another embodiment, 1.3 to 28 mol % in another embodiment, based on the total molar fraction of each component in the glass frit.

In an embodiment, boron oxide (B₂O₃) can be 15 to 48 mol %, in another embodiment 20 to 43 mol %, in another embodiment, 22 to 40 mol %, based on the total molar fraction of each component in the glass frit.

In an embodiment, aluminum oxide (Al₂O₃) can be 0.01 to 6 mol %, in another embodiment 0.09 to 4.8 mol %, in another embodiment 0.5 to 3 mol %, based on the total molar fraction of each component in the glass frit.

In another embodiment, the glass frit comprises a lead-free glass frit containing one or more of oxides selected from a group consisting of boron oxide (B₂O₃), zinc oxide (ZnO), bismuth oxide (Bi₂O₃), silicon oxide (SiO₂), aluminum oxide (Al₂O₃), and barium oxide (BaO).

In an embodiment, boron oxide (B₂O₃) can be 20 to 48 mol %, in another embodiment 25 to 42 mol %, in another embodiment, 28 to 39 mol %, based on the total molar fraction of each component in the glass frit.

In an embodiment, zinc oxide (ZnO) can be 20 to 40 mol %, in another embodiment 25 to 38 mol %, in another embodiment, 28 to 36 mol %, based on the total molar fraction of each component in the glass frit.

In an embodiment, bismuth oxide (Bi₂O₃) can be 15 to 40 mol %, in another embodiment 18 to 35 mol %, in another embodiment 19 to 30 mol % based on the total molar fraction of each component in the glass frit.

In an embodiment, silicon oxide (SiO₂) can be 0.5 to 20 mol %, in another embodiment 0.9 to 6 mol %, in another embodiment, 1 to 3 mol % in another embodiment, based on the total molar fraction of each component in the glass frit.

In an embodiment, aluminum oxide (Al₂O₃) can be 0.1 to 7 mol %, in another embodiment 0.5 to 5 mol %, in another embodiment, 0.9 to 2 mol %, based on the total molar fraction of each component in the glass frit.

In an embodiment, barium oxide (BaO) can be 0.5 to 8 mol %, in another embodiment 0.9 to 6 mol %, in another embodiment 2.5 to 5 mol %, based on the total molar fraction of each component in the glass frit.

In another embodiment, the softening point of the glass frits can be 300 to 600° C., in another embodiment 350 to 550° C. In this specification, “softening point” is determined by differential thermal analysis (DTA). To determine the glass softening point by DTA, sample glass is ground and is introduced with a reference material into a furnace to be heated at a constant rate of 5 to 20° C. per minute. The difference in temperature between the two is detected to investigate the evolution and absorption of heat from the material. In general, the first evolution peak is at the glass transition temperature (Tg), the second evolution peak is at the glass softening point (Ts), the third evolution peak is at the crystallization point. When a glass frit is a non-crystalline glass, the crystallization point would not appear in DTA.

Glass frit can be prepared by methods well known in the art. For example, the glass component can be prepared by mixing and melting raw materials such as oxides, hydroxides, carbonates, making into a cullet by quenching, followed by mechanical pulverization (wet or dry milling). Thereafter, if needed, classification is carried out to the desired particle size.

### Organic Medium

An organic medium allows constituents of a conductive powder, aluminum powder and a glass frit to be dispersed in the form of a viscous composition called “paste”, having suitable consistency and rheology for applying to a substrate by a method such as screen printing. The organic medium can be an organic resin or a mixture of an organic resin and an organic solvent.

The organic medium can be, for example, a pine oil solution or an ethylene glycol monobutyl ether monoacetate solution of polymethacrylate, or an ethylene glycol monobutyl ether monoacetate solution of ethyl cellulose, a terpineol solution of ethyl cellulose, or a texanol solution of ethyl cellulose.

In an embodiment, the organic medium can be a texanol solution of ethyl cellulose where the ethyl cellulose content is 5 wt % to 50 wt % based on the total weight of the organic medium.

A solvent can be used as a viscosity-adjusting agent. A solvent amount can be adjustable for desired viscosity. For example, a conductive paste viscosity can be 50 to 350 Pascal per second (Pa·s) when a conductive paste is applied by screen printing. The viscosity can be measured at 10 rpm and 25° C. with a Brookfield HBF viscometer with #14 spindle.

The content of the organic medium can be 5 to 50 wt % based on the total weight of the conductive paste.

The organic medium can be burned off during the firing step so that p-type electrode ideally contains no organic residue. However, actually, a certain amount of residue can remain in the resulting p-type electrode as long as it does not degrade the electrical properties of the p-type electrode.

### Additives

Additives such as a thickener, a stabilizer, a dispersant, a viscosity modifier and a surfactant can be added to a conductive paste as the need arises. The amount of the additives depends on the desired characteristics of the resulting conductive paste and can be chosen by people in the industry. Multiple kinds of the additives can be added to the conductive paste.

Although components of the conductive paste were described above, the conductive paste can contain impurities coming from raw materials or contaminated during the manufacturing process. However, the presence of the impurities would be allowed (defined as benign) as long as it does not significantly altere anticipated properties of the conductive paste. For example, the p-type electrode manufactured with the conductive paste can achieve sufficient electric properties described herein, even if the conductive paste includes benign impurities.

### Example

The present invention is illustrated by, but is not limited to, the following examples.

### Preparation of Conductive Paste

Conductive pastes to form p-type electrodes were prepared according to the following procedure by using the following materials.

Conductive powder: Spherical silver (Ag) powder with particle diameter (D50) of 3 μm as determined with a laser scattering-type particle size distribution measuring apparatus.

Aluminum (Al) powder: Spherical aluminum (Al) powder with particle diameter (D50) of 3.5 μm as determined with a laser scattering-type particle size distribution measuring apparatus.

Glass frit: Glass frit containing 50.0 mol % of PbO, 22.0 mol % of SiO₂, 2.0 mol % of Al₂O₃, 26.0 mol % of B₂O₃. The softening point determined by DTA was 434° C.

Organic medium: A texanol solution of ethyl cellulose.

Additive: a viscosity modifier.

The organic medium was mixed with the viscosity modifier for 15 minutes.

To enable the uniform dispersion of a small amount of Al powder in the conductive paste, the Ag powder and the Al powder were dispersed in the organic medium separately to mix together afterward. First, the Al powder was dispersed in some of the organic medium and mixed for 15 minutes to prepare an Al paste. Second, the glass frit was dispersed in the rest of the organic medium and mixed for 15 minutes and then the Ag powder was incrementally added to prepare Ag paste. Then, the mixture was repeatedly passed through a 3-roll mill at progressively increasing pressures from 0 to 400 psi. The gap of the rolls was adjusted to 1 mil.

Then the Ag paste and the Al paste were mixed together to prepare the conductive paste. Finally additional organic medium or thinners were mixed to adjust the viscosity of the paste. The organic medium in the conductive paste was 12 wt % based on the total weight of the conductive paste. The content of the Ag powder, the Al powder and the glass frit are shown in Table 1.

The viscosity as measured at 10 rpm and 25° C. with a Brookfield HBT viscometer with #14 spindle was 260 Pa·s. The degree of dispersion as measured by fineness of grind was 20/10 or less.

TABLE 1
(parts by weight)

| | Paste No. | | | | | | | |
|---|---|---|---|---|---|---|---|---|
| | 1 | 2 | 3 | 4 | 5 | 6 | 7 | 8 |
| Ag powder | 100 | 100 | 100 | 100 | 100 | 100 | 100 | 100 |
| Al powder | 0 | 0.6 | 1.1 | 2.3 | 3.5 | 4.8 | 6 | 12.8 |
| Glass frit | 13.6 | 13.7 | 13.8 | 14.0 | 14.1 | 14.3 | 14.5 | 15.4 |

### Manufacture of Test Pieces

The conductive paste obtained as the above was screen printed onto a SiNₓ layer with 90 nm average thickness that was formed on a p-type emitter of an n-base type of a silicon substrate (30 mm×30 mm).

The printed pattern consisted of finger lines with 80-100 μm width, 27 mm length and 20 μm thickness and a bus bar with 1.5 mm width, 28.35 mm length and 20 μm thickness. The finger lines were printed at one side of the bus bar with 2.15 mm of interval distance between the finger lines. Then the printed conductive paste was dried at 150° C. for 5 min in a convection oven.

At the other side of the silicon substrate, a commercially available silver paste was screen printed onto SiNₓ layer on the n-base layer, with a pattern consisted of finger lines with 200 μm width, 27 mm length and 20 μm thickness and a bus bar with 1.5 mm width, 28.35 mm length and 20-35 μm thickness. Then the printed Ag paste was dried at 150° C. for 5 min in a convection oven.

Electrodes were then obtained by firing the printed conductive pastes in an IR heating type of belt furnace (CF-7210, Despatch industry) at peak temperature setting with 845° C. The furnace set temperature of 845° C. corresponded to a measured temperature at the upper surface of the silicon substrate of 730° C. Firing time from furnace entrance to exit was 80 seconds. The firing condition was measured temperature less than or equal to 740° C., 400 to 600° C. for 12 seconds, and over 600° C. for 6 seconds. The temperatures were at the upper surface of the silicon substrate. The belt speed of the furnace was 550 cpm.

### Test Procedure of Efficiency

The solar cells produced according to the method described herein were tested for efficiency with a commercial IV tester (NCT-150AA, NPC Corporation). The Xe Arc lamp in the IV tester simulated the sunlight with a known intensity and spectrum to radiate with air mass value of 1.5 on the front surface with the p-type emitter of the cell. The tester was “four-point probe method” to measure current (I) and voltage (V) at approximately 400 load resistance settings to determine the cell's I-V curve. The bus bars printed on the p-type emitters, front sides of the cells, were connected to the multiple probes of the IV tester and the electrical signals were transmitted through the probes to the computer for calculating efficiencies.

### Results

The efficiency (Eff) of the test cells made using conductive pastes comprising different amount of Al powder are shown in FIG. 2. Eff of the electrode formed with the conductive paste containing 0.6, 1.1, 2.3, 3.5, 4.8, 6.0 parts by weight of Al powder was improved respectively.

### Particle Diameter of Al Powder

Next, an effect of particle diameter (D50) of the Al powder was examined. Test cell was obtained as above except that the conductive paste contains the Al powder with different particle diameter. The D50 of the Al powders were 1.5, 2.5, 3.1, 5.0, 5.7, 6.7, 7.4 or 10.6 μm respectively as shown in FIG. 3. The Al powder was 2.3 parts by weight based on the 100 parts by weight of the Ag powder. The Eff was measured in the same manner above. The Eff of the test cell were shown in FIG. 3. The Eff of the electrodes formed with the conductive pastes containing the Al powder with the particle diameter of 3.1, 5.0, 5.7, 6.7, 7.4, 10.6 μm was respectively improved.

### Firing Temperature

Next, the effect on the firing temperature was examined. The p-type electrodes were formed in the same manner of examining the Al powder content except for using a different Ag/Al paste. The used Ag/Al paste contained 100 parts by weight of the Ag powder, 1.9 parts by weight of the Al powder and 8.86 parts by weight of the glass frit. The glass frit contained 60.0 mol % of PbO, 2.0 mol % of SiO₂, 2.0 mol % of Al₂O₃, 36.0 mol % of B₂O₃. The softening point determined by DTA was 380° C.

The p-type electrode was obtained by firing the paste in an IR heating type of belt furnace (CF-7210B, Despatch industry) at setting peak temperature of 785, 805, 845, 885, 925, and 965° C., respectively.

For comparison, the p-type electrode formed with an Ag paste containing no Al powder was also prepared.

The solar cells produced according to the method described herein were tested for efficiency with a commercial IV tester (NCT-180AA-M, NPC Corporation).

The Eff obtained by the Ag/Al paste was higher than that by the Ag paste over the tested peak temperatures. Moreover, the Eff was stable and high between 805 and 965° C. as shown in FIG. 4. Accordingly, the firing temperature for the Ag/Al paste can be flexibly changed in consideration of other desired properties. This is especially beneficial for forming a p-type electrode at the same time of forming an n-type electrode by using co-firing process where the conductive pastes for the electrodes are fired at the same temperature.

### Glass Frit Content

Next, the effect of the glass frit amount was examined. The p-type electrodes were formed in the same manner as for the testing of the firing temperature above except for using different conductive pastes and adjusting the firing setting peak temperature at 845° C. The conductive paste composition is shown in Table 2. The glass frit composition was 60.0 mol % of PbO, 12.5 mol % of SiO₂, 1.0 mol % of Al₂O₃, 26.5 mol % of B₂O₃. The softening point determined by DTA was 383° C.

The Eff dramatically increased from 16.56% to over 18% by adding the glass frit more than 2.1 parts by weight as shown in Table 2.

TABLE 2

| | Paste No. | | | | |
|---|---|---|---|---|---|
| | 9 | 10 | 11 | 12 | 13 |
| Ag powder | 100 | 100 | 100 | 100 | 100 |
| Glass frit | 2.1 | 4.2 | 8.9 | 13.9 | 19.4 |
| Al powder | 1.8 | 1.8 | 1.9 | 2.0 | 2.1 |
| Eff (%) | 16.56 | 18.03 | 18.12 | 18.01 | 18.14 |

### Glass Frit Composition

Next, the p-type electrode was made by using a lead-free glass frit to see the effect on the Eff. The p-type electrodes was formed in the same manner as for the testing of the glass frit composition with Paste No. 11 in Table 2 except for using the lead-free glass frit and adjusting the firing setting peak temperature at 845° C. The glass frit composition was 33.8 mol % of B₂O₃, 1.4 mol % of SiO₂, 1.2 mol % of Al₂O₃, 33.5 mol % of ZnO, 3.4 mol % of BaO, 26.7 mol % of Bi₂O₃. The softening point determined by DTA was 471° C. The Eff was 17.94%. This result indicates that the lead-free glass frit can be useful as well as the lead containing glass frit.

What is claimed is:

1. A method of manufacturing a p-type electrode comprising the steps of:
preparing an N-type base semiconductor substrate comprising an n-base layer, a p-type emitter on the n-base layer, a first passivation layer on the p-type emitter, and a second passivation layer on the n-base layer;
applying a conductive paste onto the first passivation layer, wherein the conductive paste comprises
(i) 100 parts by weight of a conductive powder comprising a metal selected from the group consisting of silver, nickel, copper and a mixture thereof,
(ii) 0.3 to 8 parts by weight of aluminum powder with particle diameter of 3 to 11 μm,
(iii) 3 to 22 parts by weight of a glass frit, and
(iv) an organic medium; and
firing the conductive paste.

2. The method of manufacturing a p-type electrode of claim 1, wherein the glass frit comprises a lead-containing glass frit comprising one or more of oxides selected from a group consisting of lead oxide (PbO), silicon oxide (SiO₂), boron oxide (B₂O₃) and aluminum oxide (Al₂O₃); or a lead-free glass frit comprising one or more of oxides selected from a group consisting of boron oxide (B₂O₃), zinc oxide (ZnO), bismuth oxide (Bi₂O₃), silicon oxide (SiO₂), aluminum oxide (Al₂O₃), and barium oxide (BaO).

3. The method of manufacturing a p-type electrode of claim 1, wherein the softening point of the glass frit is 300 to 600° C.

4. The method of manufacturing a p-type electrode of claim 1, wherein firing time is 30 seconds to 5 minutes.

5. The method of manufacturing a p-type electrode of claim 1, wherein firing peak temperature in the firing step is 800 to 1000° C.

6. The method of manufacturing a p-type electrode of claim 1, wherein the first passivation layer is 10 to 2000 Å thick.

7. The method of manufacturing a p-type electrode of claim 1, wherein the material of the first passivation layer is Silicon nitride (SiNₓ), silicon carbide (SiCₓ), Titanium oxide (TiO₂), Aluminum oxide (Al₂O₃), Silicon oxide (SiOₓ), Indium Tin Oxide (ITO), or a mixture thereof.

8. The method of manufacturing a p-type electrode of claim 1, further comprises a step of applying a second conductive paste onto the second passivation layer, and wherein the conductive paste applied onto the first passivation layer and the second conductive paste applied onto the second passivation layer are co-fired.

9. An N-type base solar cell comprising the p-type electrode formed by the method of claim 1.
